(19) United States
(12) Patent Application Publication
(10) Pub. No.: US 2008/0002509 A1
(43) Pub. Date: Jan. 3, 2008

(54) POWER ADAPTER WITH DISCRIMINATE RECHARGING

(76) Inventor: Lin-Yuan You, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/744,203

(22) Filed: May 3, 2007

(30) Foreign Application Priority Data
Jun. 14, 2006 (TW) 095121254

(51) Int. Cl. G11C 8/00

(52) U.S. Cl. 365/230.05

(57) ABSTRACT

An adapter for charging a power storage device according to capacity data of the power storage device has a housing, a first electrical port installed on the housing for receiving external electrical power, a second electrical port installed on the housing for transmitting the external electrical power received through the first electrical port to the power storage device, a capacity data port for receiving the capacity data of the power storage device, a switch coupled between the first electrical port and the second electrical port, and a controller for controlling the switch according to the capacity data of the power storage device received by the capacity data port.

### BACKGROUND OF THE INVENTION

1. Field of the Invention

The present invention relates to power adapters, and more particularly, to a power adapter that intelligently recharges a rechargeable battery according to a power level of the rechargeable battery.

2. Description of the Prior Art

Many electronic products can use energy stored in batteries to provide electrical power required for operation, which frees users from the constraints and limitations caused by power cords. However, the electrical energy of the battery will gradually be depleted with use of the electronic device's functions. When the battery is fully depleted, such that it is no longer able to provide electrical power to the electronic device, the battery must be recharged by an external power source through a charger. Once the electrical energy is restored to the battery, the battery can resume providing the electrical power to the electronic device as required.

Generally speaking, when the user utilizes the electronic device (such as a notebook computer) in a stationary environment, such as the office, regardless of remaining charge in the battery, the user will plug the electronic device into a power supply through use of an adapter. The adapter not only provides the electrical power required to operate the notebook computer, but also simultaneously recharges the internal battery of the notebook computer. As an example of this, if the battery was previously fully charged to 100%, and the user subsequently used the notebook computer for one hour, dropping the charge to 98%, when the user plugs the adapter into the notebook computer, the adapter will begin recharging the battery, even if only 2% needs to be charged. Because the life of the rechargeable battery is dependent upon the number of times the battery is recharged, if the adapter recharges the battery every time the adapter is plugged into the notebook computer, the number of recharges will increase rapidly, and the life of the battery will be decreased correspondingly.

### SUMMARY OF THE INVENTION

According to the present invention, an adapter for charging a power storage device according to capacity data of the power storage device comprises a housing, a first electrical port installed on the housing for receiving external electrical power, a second electrical port installed on the housing for transmitting the external electrical power received through the first electrical port to the power storage device, a capacity data port for receiving the capacity data of the power storage device, a switch coupled between the first electrical port and the second electrical port, and means for controlling the switch according to the capacity data of the power storage device received by the capacity data port.

According to the present invention, an intelligent charging system comprises an electronic device comprising an electronic circuit and a power storage device coupled to the electronic circuit for providing power to the electronic circuit, and an adapter coupled between the electronic device and an external power supply. The adapter comprises a housing, a first electrical port installed on the housing for receiving power transmitted from the external power supply, a second electrical port installed on the housing for transmitting the power received by the first electrical port to the power storage device, a capacity data port for receiving capacity data of the power storage device, a switch coupled between the first electrical port and the second electrical port, and control means for controlling the switch according to the capacity data received by the capacity data port.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of an adapter coupled to an external power source and a notebook computer according to the present invention.

FIG. 2 is a functional block diagram of the adapter of FIG. 1.

### DETAILED DESCRIPTION

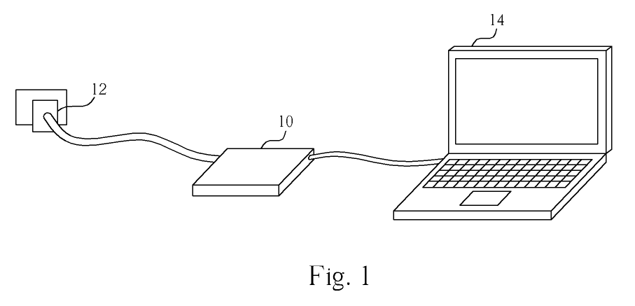

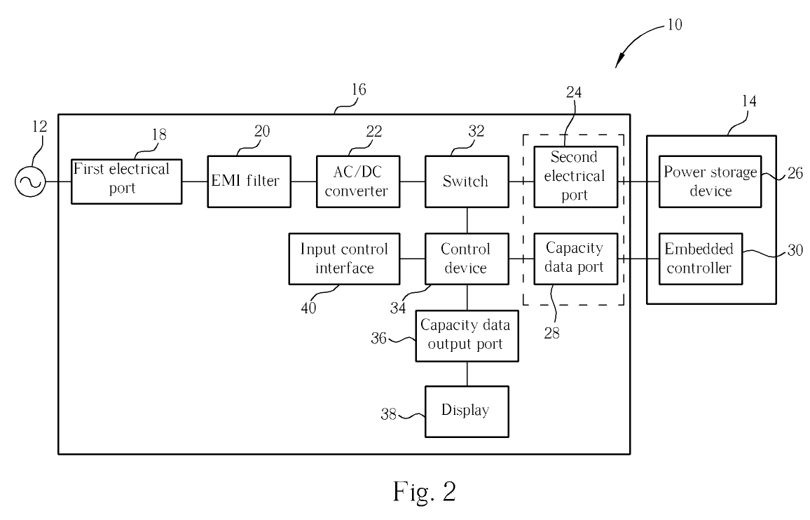

Please refer to FIG. 1 and FIG. 2, where FIG. 1 is a diagram of an adapter 10 coupled to an external power source 12 and a notebook computer 14 according to the present invention, and FIG. 2 is a functional block diagram of the adapter 10 of FIG. 1. The adapter 10 is used to receive electrical energy from the external power source 12 to recharge the notebook computer 14. The external power source 12 can be an AC (alternating current) power supply. The adapter 10 comprises a housing 16 for protecting internal electronic components, a first electrical port 18 installed on the housing 16 for receiving the electrical energy received from the external power supply 12, an EMI (electromagnetic interference) filter 20 coupled to the first electrical port 18 for filtering external EMI, and an AC/DC converter 22 for converting the AC power received by the first electrical port 18 to direct current (DC) power. The first electrical port 18 can be coupled to the external power supply 12 through a plug and an electrical socket, and the first electrical port 18 can comprise a power prong and a ground prong. The AC/DC converter 22 can be a flyback converter, or another type of AC/DC converter. The adapter 10 further comprises a second electrical port 24 installed on the housing 16 for transmitting the electrical power received by the first electrical port 18 to an power storage device 26 of the notebook computer 14. The power storage device 26 can be a battery of the notebook computer 14. The second electrical port 24 can comprise a power prong and a ground prong. The adapter 10 further comprises a capacity data port 28 installed on the housing 16 for receiving capacity data of the power storage device 26 transmitted from an embedded controller 30 of the notebook computer 14. The capacity data port 28 can conform to a System Management Bus (SM Bus) standard, and can comprise a data prong and a clock (CLK) prong. The second electrical port 24 and the capacity data port 28 can be physically connected to the notebook computer 14 in a common plug. The adapter 10 further comprises a switch 32, which can be a MOSFET switch, etc., coupled between the first electrical port 18 and the second electrical port 24, and a control device 34 for controlling the switch 32 according to the capacity data of the power storage device 26 received by the capacity data port 28. The control device 34 can be program code stored in an electrically erasable programmable ROM (EEPROM) or a control IC, etc. The adapter 10 further comprises a capacity data output port 36, which can conform to a general purpose input/output (GPIO) standard, coupled to the control device 34 for outputting capacity data corresponding to the capacity data of the power storage device 26 received by the capacity data port 28, and a display 38 coupled to the capacity data output port 36 for displaying the capacity data outputted by the capacity data output port 36. The display 38 can be a plurality of light-emitting diodes (LED). In addition, the adapter 10 further comprises an input control interface 40 coupled to the control device 34 for inputting a control command to the control device 34. For example, the control command could be inputted to the control device 34 to control the capacity data port 28 to read the capacity data of the power storage device 26, or the control command could be inputted to the control device 34 to keep the switch 32 turned on. The input control interface 40 could be a button, etc.

The following is a detailed description of the operating principle of the adapter 10 of the present invention. The power storage device 26 of the notebook computer 14 can transmit its capacity data to the embedded controller 30. Then, the embedded controller 30 can transmit the capacity data of the power storage device 26 to the control device 34 through the capacity data port 28. For example, the power storage device 26 can notify the embedded controller 30 that the power storage device 26 is currently in a low power or a full power state. When the embedded controller 30 received the notification from the power storage device 26, the embedded controller 30 can send a control command to the control device 34 of the adapter 10 through the capacity data port 28. For example, a threshold can be set, such that when the power of the power storage device 26 is greater than the threshold, the embedded controller 30 can output a notification corresponding to a full power state to the control device 34. When the power of the power storage device 26 is less than the threshold, the embedded controller can output a notification corresponding to an insufficient power state to the control device 34. After the control device 34 receives the notification transmitted from the embedded controller 30 through the capacity data port 28, the control device 34 can turn the switch 32 on or off according to the notification received. When the control device 34 receives the notification corresponding to the insufficient power state, the control device 34 can turn on the switch 32. Or, when the power of the power storage device 26 is greater than the threshold, the embedded controller 30 can not send any notification to the control device 34; and, when the power of the power storage device 26 is less than the threshold, the embedded controller 30 can output the control notification to the control device 34. When the control device 34 has not received the control notification transmitted from the embedded controller 30 through the capacity data port 28, the control device 34 can initially turn off the switch 32; however, when the control device 34 receives the control notification transmitted from the embedded controller 30, the control device 34 can turn on the switch 32.

When the switch 32 is turned off, the first electrical port 18 is decoupled from the second electrical port 24. At this time, the second electrical port 24 is unable to transfer power to the power storage device 26. In other words, the second electrical port 24 is unable to recharge the power storage device 26 of the notebook computer 14. When the switch 32 is turned on, the first electrical port 18 is coupled to the second electrical port 24. At this time, the second electrical port 24 can transfer power to the power storage device 26, i.e. the second electrical port 24 can begin recharging the power storage device 26 of the notebook computer 14. In summary, when the power state of the power storage device 26 is the full power state, the switch 32 is turned off, so that the adapter 10 cannot recharge the power storage device 26 of the notebook computer 14. On the other hand, when the power state of the power storage device 26 is the insufficient power state, the switch 32 is turned on, so that the adapter 10 can recharge the power storage device 26 of the notebook computer 14. In this way, the adapter 10 can decide whether or not to recharge the power storage device 26 of the notebook computer 14 based on the power state of the rechargeable power storage device 26.

Further, the control device 34 can output the capacity data of the power storage device 26 received through the capacity data port 28 to the display 38 through the capacity data output port 36. The display 38 can represent the capacity data in a visual or aural way. For example, the display 38 can comprise a plurality of light-emitting diodes (LED), such that the capacity data of the power storage device 26 can be displayed by whether or not the plurality of LEDs is lit. In other words, when the power level of the power storage device 26 is low, fewer LEDs in the plurality of LEDs can be lit; when the power level of the power storage device 26 is relatively high, more LEDs of the plurality of LEDs can be lit. The display 38 could also be a speaker. When the power storage device 26 is in the insufficient power state, the display 38 could emit a sound to alert the user. Another advantage of utilizing the display 38 to display the capacity data of the power storage device 26 is that the notebook computer 14 does not need to be turned on for the embedded controller 30 to transmit the capacity data of the power storage device 26 to the capacity data port 28, so that the display 38 of the adapter 10 can display the capacity data of the power storage device 26, whereby the user can know the power level of the power storage device 26 without first having to turn on the notebook computer 14. Additionally, a switch can be added to the display 38, such that the user can turn on the switch to start the function of the display 38 for displaying the power level of the power storage device 26. Finally, the user can use the input control interface 40 to input the control command to the control device 34 to control the capacity data port 28 to read the data of the power storage device 26, e.g. capacity data or temperature data of the power storage device 26.

The control device 34 can further be used to determine if the power storage device 26 is coupled to the adapter 10. If the power storage device 26 is not coupled to the adapter 10, the control device 34 can control the switch 32 to turn on. Namely, when the notebook computer 14 does not have the power storage device 26 installed, intelligent recharging as described above does not need to be performed according to the capacity data of the power storage device 26. The embedded controller 30 can output a corresponding control notification to the control device 34, such that the control device 34 turns on the switch 32 to maintain coupling between the first electrical port 18 and the second electrical port 24 and directly provide power to the notebook computer 14. The user can also use the input control interface 40 to input the control command to the control device 34 to make the control device 34 to control the switch 32 to remain turned on, i.e. canceling the intelligent recharging function of the adapter, and cause the adapter 10 to act as a general recharging adapter with only the recharging function.

Compared to the adapter of the prior art, the present invention adapter can determine whether or not to recharge the battery of the notebook computer according to the power level of the battery of the notebook computer. In this way, the battery can be charged only when the battery is in a lower power state, which reduces the number of times the battery is recharged, and extends the life of the battery. The present invention also makes normal use of the adapter more convenient for the conscientious user, as the user no longer has to worry about plugging in the adapter when the battery is already charged. The adapter can be plugged into the notebook computer at any time without causing harm to the battery. The present invention also eliminates repetitive plugging in and unplugging of the adapter, which can wear down the socket in the notebook computer. Finally, the present invention makes it unnecessary for the user to turn on the notebook computer to determine the power level of the battery. Instead, the user can simply refer to the display on the adapter, which indicates the power level of the battery directly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An adapter for charging a power storage device according to capacity data of the power storage device comprising:
a housing;
a first electrical port installed on the housing for receiving external electrical power;
a second electrical port installed on the housing for transmitting the external electrical power received through the first electrical port to the power storage device;
a capacity data port for receiving the capacity data of the power storage device;
a switch coupled between the first electrical port and the second electrical port; and
means for controlling the switch according to the capacity data of the power storage device received by the capacity data port.

2. The adapter of claim 1, wherein the first electrical port is used to receive alternating current (AC) power.

3. The adapter of claim 2 further comprising an alternating current/direct current (AC/DC) converter for converting the AC power received by the first electrical port to DC power.

4. The adapter of claim 3, wherein the AC/DC converter is a flyback converter.

5. The adapter of claim 1 further comprising an electromagnetic interference (EMI) filter coupled to the first electrical port for filtering external EMI.

6. The adapter of claim 1, wherein when the capacity data of the power storage device received by the capacity data port is greater than a threshold, the control means is used to turn off the switch to decouple the first electrical port from the second electrical port.

7. The adapter of claim 1, wherein when the capacity data of the power storage device received by the capacity data port is lower than a threshold, the control means is used to turn on the switch to couple the first electrical port to the second electrical port.

8. The adapter of claim 1, wherein the switch is a metal-oxide-semiconductor field effect transistor (MOSFET) switch.

9. The adapter of claim 1 further comprising a capacity data output port for outputting capacity data according to the capacity data of the power storage device received by the capacity data port.

10. The adapter of claim 9 further comprising a display coupled to the capacity data output port for displaying the capacity data output by the capacity data output port.

11. The adapter of claim 10, wherein the display is a light-emitting diode (LED).

12. The adapter of claim 1, wherein the capacity data port conforms to a System Management Bus (SM Bus) standard.

13. The adapter of claim 1, wherein the control means is program code stored in an electrically erasable programmable ROM (EEPROM).

14. The adapter of claim 1, wherein the capacity data port is utilized for receiving the capacity data of the power storage device transmitted from an embedded controller.

15. The adapter of claim 1, wherein the control means is further utilized for determining whether the power storage device is coupled to the adapter, and for controlling the switch to stay on when the power storage device is not coupled to the adapter.

16. An intelligent charging system comprising:
an electronic device comprising:
an electronic circuit; and
a power storage device coupled to the electronic circuit for providing power to the electronic circuit; and
an adapter coupled between the electronic device and an external power supply, the adapter comprising:
a housing;
a first electrical port installed on the housing for receiving power transmitted from the external power supply;
a second electrical port installed on the housing for transmitting the power received by the first electrical port to the power storage device;
a capacity data port for receiving capacity data of the power storage device;
a switch coupled between the first electrical port and the second electrical port; and
means for controlling the switch according to the capacity data received by the capacity data port.

17. The intelligent charging system of claim 16, wherein the control means decouples the first electrical port from the second electrical port by controlling the switch to turn off when the capacity data of the power storage device received by the capacity data port is greater than a threshold.

18. The intelligent charging system of claim 16, wherein the control means couples the first electrical port to the second electrical port by controlling the switch to turn off when the capacity data of the power storage device received by the capacity data port is lower than a threshold.

19. The intelligent charging system of claim 16, wherein the control means is further utilized for determining whether the power storage device is coupled to the adapter, and for controlling the switch to stay on when the power storage device is not coupled to the adapter.

20. The intelligent charging system of claim 16, wherein the adapter further comprises a capacity data output port for outputting capacity data according to the capacity data of the power storage device received by the capacity data port.

21. The intelligent charging system of claim 20, wherein the adapter further comprises a display coupled to the capacity data output port for displaying the capacity data outputted by the capacity data output port.

22. The intelligent charging system of claim 16, wherein the capacity data port can receive the capacity data of the power storage device when the electronic circuit is off.

23. The intelligent charging system of claim 16 further comprising an input control interface coupled to the control means for inputting a control command to the control means.

24. The intelligent charging system of claim 23, wherein the input control interface is a button.

25. The intelligent charging system of claim 23, wherein the input control interface can control the capacity data port to read data of the power storage device by entering the command to the control means.

26. The intelligent charging system of claim 23, wherein the input control interface can control the control means to control the switch to stay on by entering the command to the control means.
